(19) United States
(12) Patent Application Publication
(10) Pub. No.: US 2008/0020259 A1
(43) Pub. Date: Jan. 24, 2008

(54) CURRENT COLLECTION BOARD FOR FUEL CELL

(76) Inventors: Hsi-Ming Shu, Taipei (TW); Wei-Li Huang, Taipei (TW)

Correspondence Address: G. LINK CO ., LTD, 3550 BELL ROAD, MINOOKA, IL, 60447, US

(21) Appl. No.: 11/459,394

(22) Filed: Jul. 24, 2006

(51) Int. Cl. H01M 8/02; H05K 7/00

(52) U.S. Cl. 429/34; 361/748

(57) ABSTRACT

A current collection board for a fuel cell comprises a substrate and current collection bars. The substrate includes at least one current collection region. The current collection bars are arranged corresponding to the current collection region; wherein each of the current collection bar includes a metallic pillar with copper covered by stainless steel.

### FIELD OF THE INVENTION

The present invention relates to a current collection board for a fuel cell, and more particularly, to a current collection board combining a printed circuit substrate and a metallic pillar having stainless steel covered copper, which is easily fabricated at low cost.

### BACKGROUND OF THE INVENTION

A conventional fuel cell includes components such as an anode current collection board, a cathode current collection board and at least one membrane electrode assembly (MEA), wherein these components are assembled compactly to form the cell. Consequently, the anode current collection board and the cathode current collection board applied to certain types of fuel cells are not suitable for other types of cells. It is also difficult with respect to the traditional structures of the anode current collection board and the cathode current collection board to fit them for manifold MEAs, especially for newly-developed MEAs. As a result, such newly-developed MEAs' quality is not tested and verified unless another special anode current collection board and cathode current collection board are manufactured.

In prior arts, graphite plates have been applied to conventional current collection boards. Though graphite plates are able to collect current, they are physically fragile. It is thus not economic to make current collection boards from graphite plates. Furthermore, graphite plates occupy a large amount of space, so the current collection boards made thereby are not minimized accordingly.

Therefore, an improved current collection board that is easily fabricated at low cost is needed to overcome the aforesaid disadvantages.

### SUMMARY OF THE INVENTION

It is a primary object of the invention to provide a current collection board of a fuel cell, which combines the features of a printed circuit substrate with a metallic pillar with copper covered by stainless steel. Hence, the current collection board is easily fabricated at low cost.

In accordance with the aforesaid objects of the invention, a current collection board of a fuel cell is provided, which comprises a substrate and at least one current collection bar. The substrate includes at least one current collection region. The current collection bar is arranged corresponding to the current collection region; wherein the current collection bar includes a metallic pillar with copper covered by stainless steel.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 is an exploded diagram showing a current collection board of a fuel cell according to an embodiment of the invention;

FIG. 2 illustrates the perspective view of FIG. 1;

FIG. 3 shows the structure of a current collection bar according to an embodiment of the invention;

FIG. 4 shows the body of a plate according to another embodiment of the invention; and

FIG. 5 illustrates the cross-section of a current collection bar according to another embodiment of the invention.

### DETAILED DESCRIPTION OF THE INVENTION

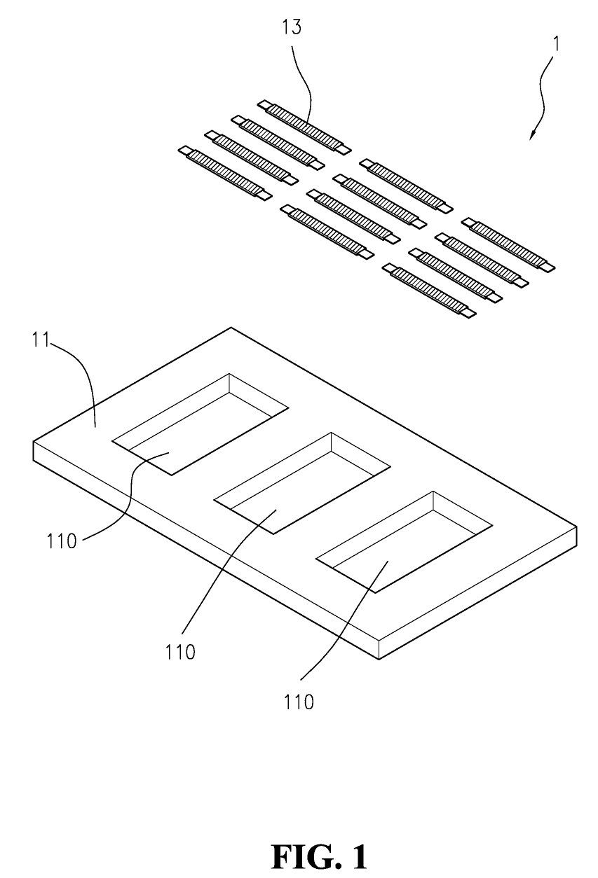

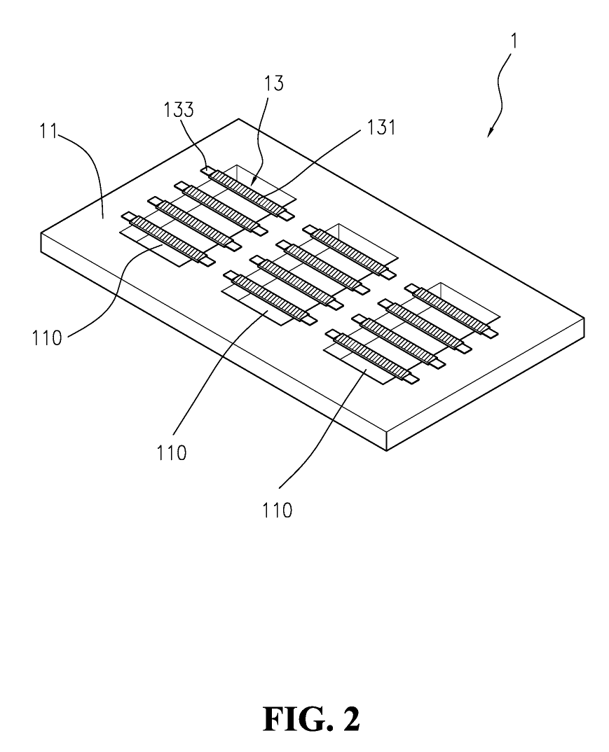

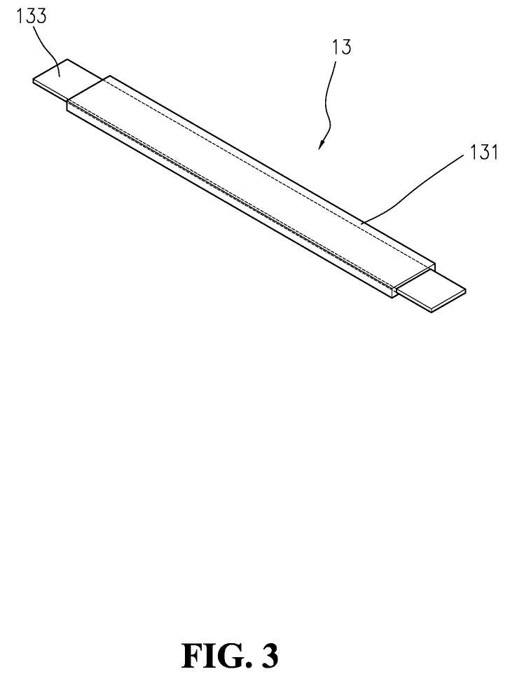

FIG. 1 is an exploded diagram showing a current collection board of a fuel cell according to an embodiment of the invention. FIG. 2 illustrates the perspective view of FIG. 1. FIG. 3 shows the structure of a current collection bar according to an embodiment of the invention. A current collection board 1 comprises a substrate 11 and a plurality of current collection bars 13. The substrate may be made of a printed circuit substrate, such as a FR4 substrate, a FR5 substrate, an epoxy resin substrate, a glass fiber substrate, a ceramic substrate, a polymeric plastic substrate, or a composite substrate. One or more current collection regions 110 are disposed over the substrate 11 corresponding to the positions of membrane electrode assemblies (MEAs) (not shown). The current collection regions 110 are formed by, for example, digging a plurality of hollow portions within the substrate 11. As such, fuels pass through the hollow portions 110 and flow into the MEAs, respectively. Also, the products produced during electrochemical reactions in the MEAs pass through the hollow portions 110 and drain away.

The current collection bar 13 may include a metallic pillar with a copper axis covered by stainless steel. Referring to FIG. 3, the current collection bar 13 may be a flat metallic pillar, and each metallic pillar 13 includes a solid or hollow axis 133 of metal copper covered by an outer layer 131 of stainless steel. As the current collection board 1 is assembled, the current collection bars 13 are used to cover each hollow portion 110. In addition, the shapes and sizes of the accompanying MEAs are considered when assembling the hollow portions. Preferably, the outer layers 131 of stainless steel of the current collection bars 13 are deployed corresponding to the MEAs averagely.

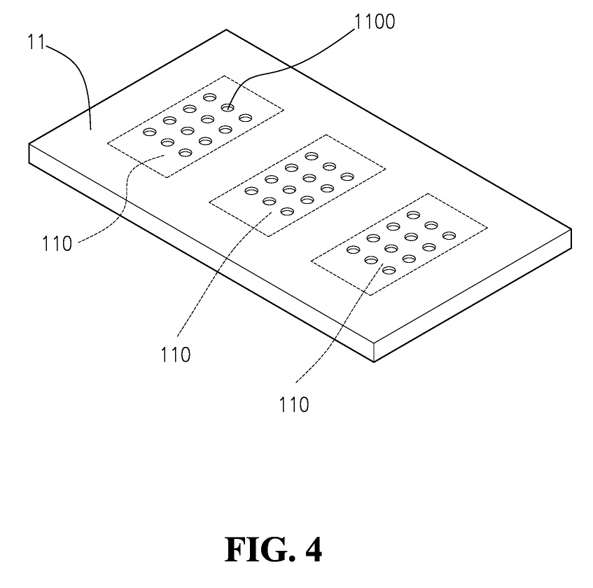

FIG. 4 shows a substrate according to another embodiment of the invention. Pluralities of through holes 1100 are disposed in a hollow portion 110 of the substrate 11, and penetrate through the substrate 11 in the z-direction (thickness). As such, fuels pass through the through holes 1100 and flow into the MEAs. Also, the products produced during electrochemical reactions in the MEAs pass through the through holes 1100 and drain away.

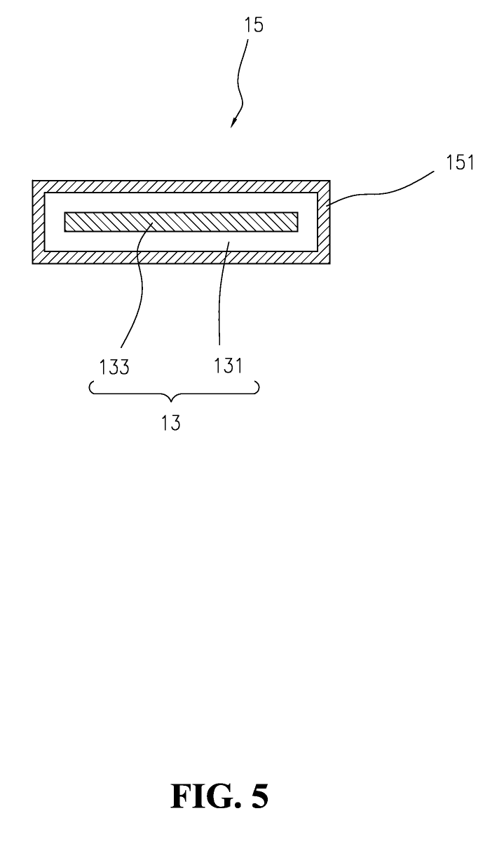

FIG. 5 illustrates the cross-section of a current collection bar according to another embodiment of the invention. For accommodating a current collection bar 15 to various conditions of fuels, the most outer surface of the current collection bar 13 in FIG. 3 is further treated by a protection process and/or an anticorrosive/acid-proof process. The most outer surface of the current collection bar 13 in FIG. 3 is plated with a thin metal layer of gold (Ag) 151. Consequently, the current collection bar 15 of FIG. 5 is not damaged by corrosion from fuels, and the performance of the current collection bar 15 is enhanced.

The current collection bars 13, 15 within each current collection region 110 are electrically connected altogether. The current collection bars 13, 15 are electrically connected by, for example, soldering the current collection bars 13, 15 onto a metallic lamina (not shown), and then fixing the metallic lamina on the substrate 11. Accordingly, the current generated by a corresponding MEA flows from the anode of the MEA, through the outer layers 131 of stainless steel of the current collection bars 13, 15, which are in electrical communication with the anode of the MEA, and through the metal copper 133 and the loadings in turn, and then flows towards the current collection bars 13, 15 of another current collection board 11, which are in electrical communication with the cathode of the aforesaid MEA, so as to form a current loop.

The current collection board 1 above may be applied to manifold fuel cells, such as a fuel cell with methanol fuels, a fuel cell with liquid fuels, a fuel cell with gaseous fuels, or a fuel cell with solid fuels.

The aforementioned current collection board combines the benefits of a printed circuit substrate with the physical properties of at least two kinds of metals, so it has the following advantages and improvements:

1. The substrate of the current collection board is fabricated from a printed circuit substrate, which is less expensive and processed easily. Furthermore, the metallic pillar having stainless steel covered copper is easily fabricated at low cost. So the current collection board made thereby is favorable for mass production.

2. In addition to possessing the ability of collecting current, the surface of the current collection bar is further treated by a protection process and/or an anticorrosive/acid-proof process. Therefore, the current collection bar has a longer lifetime and an improved ability of collecting current.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. A current collection board for a fuel cell, the current collection board comprising:
a substrate including at least one current collection region; and
at least one current collection bar arranged corresponding to the current collection region, wherein the current collection bar includes a metallic pillar with copper covered by stainless steel.

2. The current collection board of claim 1, wherein a substrate of the substrate comprises a printed circuit substrate.

3. The current collection board of claim 2, wherein the substrate of the substrate is an FR4 substrate, an FR5 substrate, an epoxy resin substrate, a glass fiber substrate, a ceramic substrate, a polymeric plastic substrate, or a composite substrate.

4. The current collection board of claim 1, wherein the current collection bar is flat.

5. The current collection board of claim 1, wherein the current collection bar is soldered on the substrate, and covers a corresponding current collection region.

6. The current collection board of claim 1, wherein the current collection bars corresponding to a current collection region are electrically connected altogether.

7. The current collection board of claim 1, wherein the surface of the current collection bar is treated by a protection process and/or an anticorrosive/acid-proof process.

8. The current collection board of claim 1, wherein the current collection bar further comprises a gilded layer covering the stainless steel.

9. The current collection board of claim 1, wherein the current collection region is disposed on a hollow portion of the substrate.

10. The current collection board of claim 1, wherein the current collection region is disposed on a plurality of through holes of the substrate.
